(19) United States
(12) Patent Application Publication
(10) Pub. No.: US 2014/0291666 A1
(43) Pub. Date: Oct. 2, 2014

(54) FLIP-CHIP SOLID STATE LIGHT DISPLAY

(71) Applicant: HON HAI PRECISION INDUSTRY CO., LTD., New Taipei (TW)

(72) Inventor: JIAN-SHIHN TSANG, Tu-Cheng (TW)

(73) Assignee: HON HAI PRECISION INDUSTRY CO., LTD., New Taipei (TW)

(21) Appl. No.: 14/181,730

(22) Filed: Feb. 17, 2014

(30) Foreign Application Priority Data
Mar. 27, 2013 (TW) 102110975

(51) Int. Cl. H01L 27/15; H01L 33/48

(52) U.S. Cl. CPC H01L 27/153; H01L 33/486
USPC 257/43; 257/59; 257/72

(57) ABSTRACT

An exemplary flip-chip solid state light display includes a substrate, a plurality of solid state lighting elements and a plurality of thin film transistors; the solid state lighting elements and the thin film transistors are located on the substrate, and the solid state lighting elements each are adjacent to one respective thin film transistor. The solid state lighting elements each are a light emitting diode, and are mounted on the substrate by a way of flip-chip. The thin film transistors each electrically connect with a corresponding solid state element by a source electrode or a drain electrode of each of the thin film transistors.

### BACKGROUND

1. Technical Field

This disclosure generally relates to solid state light displays, and particularly to a flip-chip solid state light display comprising flip-chip solid state lighting elements having stable and reliable performance.

2. Description of Related Art

A typical active matrix organic light emitting display (AMOLED) includes a plurality of organic light emitting elements functioning as light source. However, in a manufacturing process of the active matrix organic light emitting display, the organic light emitting materials are prone to be affected by environmental factors, such as moisture, which cause the organic materials to be deteriorated. Therefore, the manufacturing process of the active organic light emitting display needs to be performed in a vacuum environment to avoid the deterioration of the organic materials, resulting in a complicated manufacturing process. In addition, the deterioration of the organic light emitting materials shortens the service life of the active organic light emitting display.

What is needed, therefore, is a flip-chip solid state light display which can overcome the above-described shortcoming.

### BRIEF DESCRIPTION OF THE DRAWINGS

FIG. 1 is a cross-sectional view of a flip-chip solid state light display according to a first embodiment of the present disclosure.

FIG. 2 is a cross-sectional view of a flip-chip solid state light display according to a second embodiment of the present disclosure.

FIG. 3 is a cross-sectional view of the flip-chip solid state light display of FIG. 1 with a phosphor layer.

FIG. 4 is a cross-sectional view of the flip-chip solid state light display of FIG. 2 with a phosphor layer.

### DETAILED DESCRIPTION

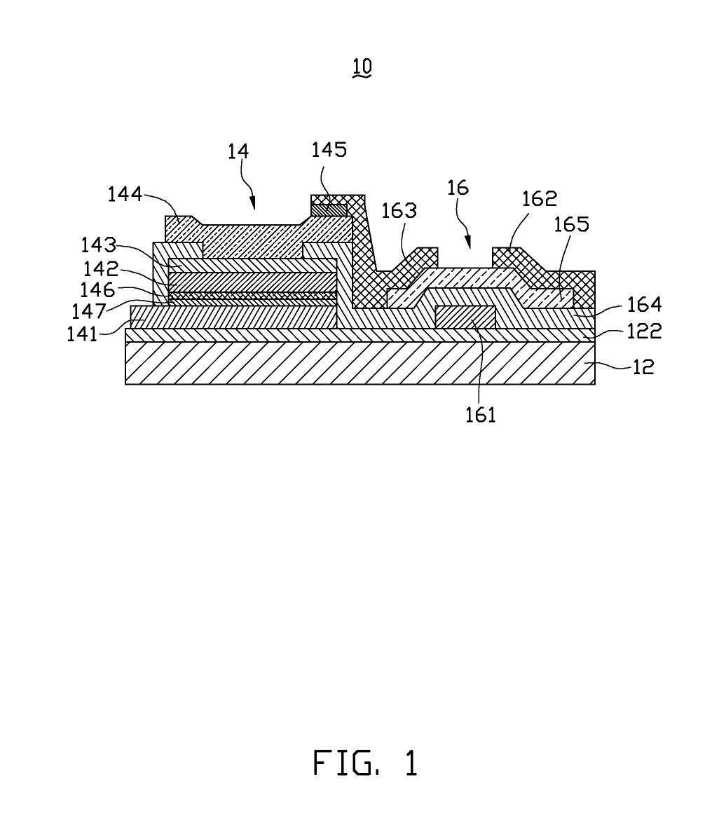

Referring to FIG. 1, a flip-chip solid state light display 10 in accordance with a first embodiment of the present disclosure is provided.

The flip-chip solid state light display 10 includes a substrate 12, a plurality of solid state lighting elements 14, and a plurality of thin film transistors 16. In the figure, only one solid state lighting element 14 and one thin film transistor 16 are shown.

The substrate 12 is made of sapphire, silicon, silicon on insulator (SOI), glass, GaN, ZnO or plastic. A buffer layer 122 is arranged on a top surface of the substrate 12. The buffer layer 122 is electrically insulated. The solid state lighting elements 14 and the thin film transistors 16 are arranged on the buffer layer 122. The solid state lighting elements 14 each are a light emitting diode (LED). The solid state lighting element 14 is mounted on the substrate 12 by a way of flip-chip. The solid state lighting element 14 is an oxide semiconductor, a nitride semiconductor, a phosphide semiconductor, or an arsenide semiconductor. The solid state lighting element 14 may be a compound semiconductor, including III-V semiconductors, II-VI semiconductors, or IV-IV semiconductors. In this embodiment, the solid state lighting element 14 is a P-N type light emitting diode, and includes a p-type electrode 141, a p-type semiconductor layer 142, a light emitting layer 143, an n-type semiconductor layer 144 and an n-type electrode 145.

The p-type electrode 141 is formed on the buffer layer 122. The p-type electrode 141 is a metal block or a thin metal film. The p-type semiconductor layer 142 is formed over the p-type electrode 141. The light emitting layer 143 is arranged on the p-type semiconductor layer 142. The n-type semiconductor layer 144 is arranged on the light emitting layer 143. The n-type electrode 145 is arranged on the n-type semiconductor layer 144. The p-type semiconductor layer 142 is fixed to the substrate 12 by the p-type electrode 141, wherein a bottom surface of the p-type semiconductor 142 is near to the p-type electrode 141. Because the solid state lighting element 14 is a flip-chip light emitting diode and the p-type semiconductor layer 142 is close to the substrate 12, heat generated by the p-type semiconductor layer 142 can be conducted to the substrate 12, and then dissipated quickly by the substrate 12, which maintains the stability of the p-type semiconductor layer 142 and increases the reliability of the solid state lighting element 14.

The n-type semiconductor layer 144 can be a metal oxide semiconductor, such as ZnO or IGZO, or a compound semiconductor, such as ZnSe, GaAs, InGaAlP or AlInGaN. In this embodiment, the n-type semiconductor layer 144 may be a transparent metal oxide semiconductor, and it may electrically connect with the thin film transistor 16.

A contact layer 146 and a current spreading layer 147 are located between the p-type semiconductor layer 142 and the p-type electrode 141. The current spreading layer 147 is a low resistant layer to help the p-type electrode 141 to spread the current, which increases the lighting efficiency of the solid state lighting element 14.

The thin film transistor 16 is located at a lateral side of the solid state lighting element 14. The thin film transistor 16 includes a gate electrode 161, a source electrode 162, and a drain electrode 163. The gate electrode 161 is located below the source electrode 162 and the drain electrode 163, and on the buffer layer 122 which is on the substrate 12. The source electrode 162 and the drain electrode 163 are located above the gate electrode 161 to electrically connect with the solid state lighting element 14.

An insulation layer 164 is located between the solid state lighting element 14 and the thin film transistor 16. The insulation layer 164 is located above the gate electrode 161, and covers the gate electrode 161. An active layer 165 is arranged on the insulation layer 164. The source electrode 162 and the drain electrode 163 are located on the active layer 165. The insulation layer 164 insulates the gate electrode 161 and the source electrode 162, and also insulates the gate electrode 161 and the drain electrode 163. The insulation layer 164 is used as a gate insulation layer. The thin film transistor 16 can be electrically connected to the solid state lighting element 14 by the source electrode 162 or the drain electrode 163.

In the first embodiment, the source electrode 162 or the drain electrode 163 of the thin film transistor 16 electrically connects with the solid state lighting element 14 by the n-type semiconductor layer 144. The n-type semiconductor layer 144 can be a metal oxide semiconductor or a transparent metal oxide layer. Alternatively, the source electrode 162 or the drain electrode 163 can electrically connect with the n-type electrode 145 on the n-type semiconductor layer 144.

Alternatively, the source electrode 162 or the drain electrode 163 can electrically connect with the solid state lighting element 14 by the source electrode 162 or the drain electrode 163 electrically connecting with the p-type semiconductor layer 142, or the current spreading layer 147, or the p-type electrode 141.

The light emitting layer 143 of the solid state lighting element 14 is made of CdZnMgSeTe, AlGaInP, AlInGaAs, AlInGaN, ZnO, IGZO, or SiGe.

The thin film transistor 16 is a polysilicon thin film transistor, a transparent metal oxide thin film transistor or an oxide semiconductor thin film transistor. The active layer 165 of the thin film transistor 16 is a metal oxide semiconductor, a low temperature poly-silicon (LTPS), or an amorphous silicon (a-Si). The metal oxide semiconductor is an amorphous metal oxide semiconductor, poly-silicon metal oxide semiconductor, crystalline metal oxide semiconductor, microcrystalline metal oxide semiconductor, or a nano metal oxide semiconductor. The active layer 165 of the thin film transistor 16 contains In, Ca, Al, Zn, Cd, Ca, Mg, Sn or Pb. Preferably, the active layer 165 is an IGZO (indium gallium zinc oxide) layer. The material for forming the active layer 165 can also be used for forming the current spreading layer 147 of the solid state lighting element 14 which can be transparent.

The insulation layer 164 can be selected from SiOₓ, SiON, SiNₓ, HfOₓ, AlOₓ, Ta₂O₅ or BaSrTiOₓ. At least one of the source electrode 162 and the drain electrode 163 is a transparent oxide electrode, or a metal electrode, or a transparent nonmetallic electrode. The transparent oxide electrode includes ITO (Indium Tin Oxide), IZO (Indium Zinc Oxide), IGZO, AZO (Al-doped Zn Oxide), or ATO (Antimony Tin Oxide). The metal electrode contains one composition of nickel (Ni), titanium (Ti), chromium (Cr), aluminum (Al), gold (Au), silver (Ag), molybdenum (Mo), copper (Cu), platinum (Pt), palladium (Pd), cobalt (Co), tungsten (W), or an alloy thereof. The transparent nonmetallic electrode is made of graphene, carbon nanotubes (CNT) or graphite powder.

According to the flip-chip solid state light display 10, because the solid state lighting element 14 is made of an oxide semiconductor, a nitride semiconductor, a phosphide semiconductor, an arsenide semiconductor or a compound semiconductor, the deterioration problem in the manufacturing process is avoided by the properties of the semiconductors which are not so easily affected by the environmental conditions. Meanwhile, the solid state lighting element 14 is a flip-chip light emitting diode, whereby cooling efficiency is increased to maintain the stability and reliability of the flip-chip solid sate light display 10.

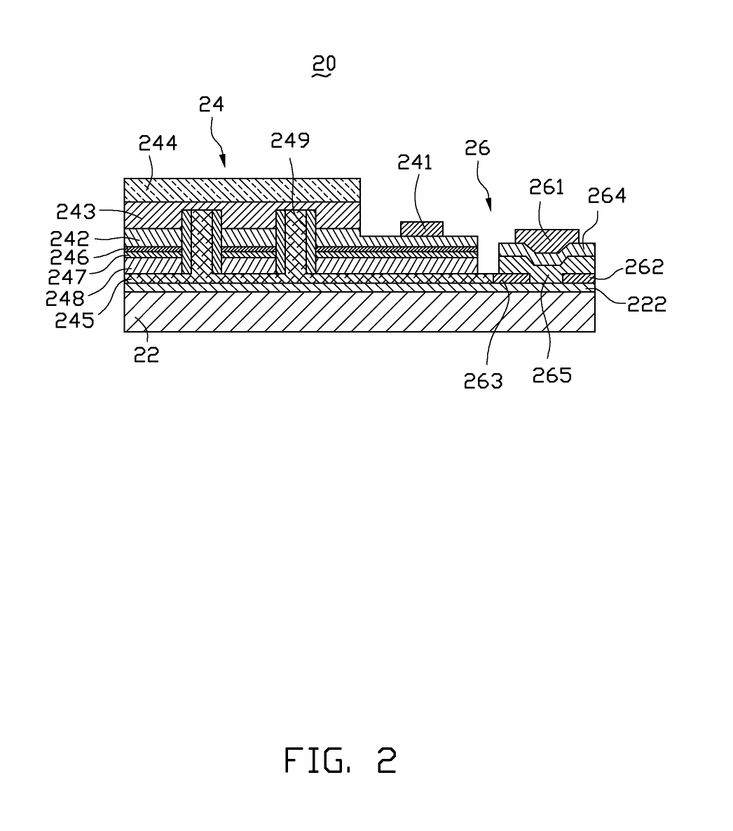

Referring to FIG. 2, a flip-chip solid state light display 20 according to a second embodiment of the present disclosure is provided. The solid state light display 20 includes a substrate 22, a plurality of solid state lighting elements 24 (only one is shown), and a plurality of thin film transistors 26 (only one is shown). An insulation layer 222 is arranged on a top surface of the substrate 22. The solid state lighting element 24 and the thin film transistor 26 are arranged on the insulation layer 222. The solid state lighting element 24 is a P-N type light emitting diode. The solid state lighting element 24 includes a p-type electrode 241, a p-type semiconductor layer 242, a light emitting layer 243, an oxide semiconductor layer 244 and an n-type electrode 245.

Compared to the solid state light display 10 in the first embodiment, the difference is that the solid state lighting element 24 is fixed on the substrate 22 by the n-type electrode 245, and the n-type electrode 245 extends through a through hole 249 to electrically connect with the light emitting layer 243 or the oxide semiconductor layer 244. In this embodiment, the n-type electrode 245 extends through the through hole 249 to contact with the light emitting layer 243. Alternatively, the n-type electrode 245 extends through the through hole 249 to contact with the oxide semiconductor layer 244 if the oxide semiconductor layer 244 is a metal oxide semiconductor. The through hole 249 extends through the p-type semiconductor layer 242. The n-type electrode 245 is electrically insulated from the p-type semiconductor layer 242 by an insulator (not labeled) around the through hole 249.

In the second embodiment, the solid state lighting element 24 includes a contact layer 246, a current spreading layer 247 and a distributed bragg reflector (DBR) layer 248. The contact layer 246, the current spreading layer 247 and the distributed bragg reflector layer 248 are located between the p-type semiconductor layer 242 and the n-type electrode 245. The contact layer 246, the current spreading layer 247 and the distributed bragg reflector layer 248 corporately help increase the lighting efficiency of the solid state lighting element 24.

The n-type electrode 245, the source electrode 262 of the thin film transistor 26, the drain electrode 263 of the thin film transistor 26 are arranged on the top surface of the insulation layer 222 which is on the substrate 22. The gate electrode 261 of the thin film transistor 26 is arranged on the top of the thin film transistor 26. The source electrode 262 or the drain electrode 263 electrically connects with the n-type electrode 245 on the substrate 22. In this embodiment, the drain electrode 263 electrically connects with the n-type electrode 245. An active layer 265 is located above the source electrode 262 and the drain electrode 263, and the active layer 265 separates the source electrode 262 from the drain electrode 263. An insulation layer 264 is located on the active layer 265. The gate electrode 261 is located on the insulation layer 264.

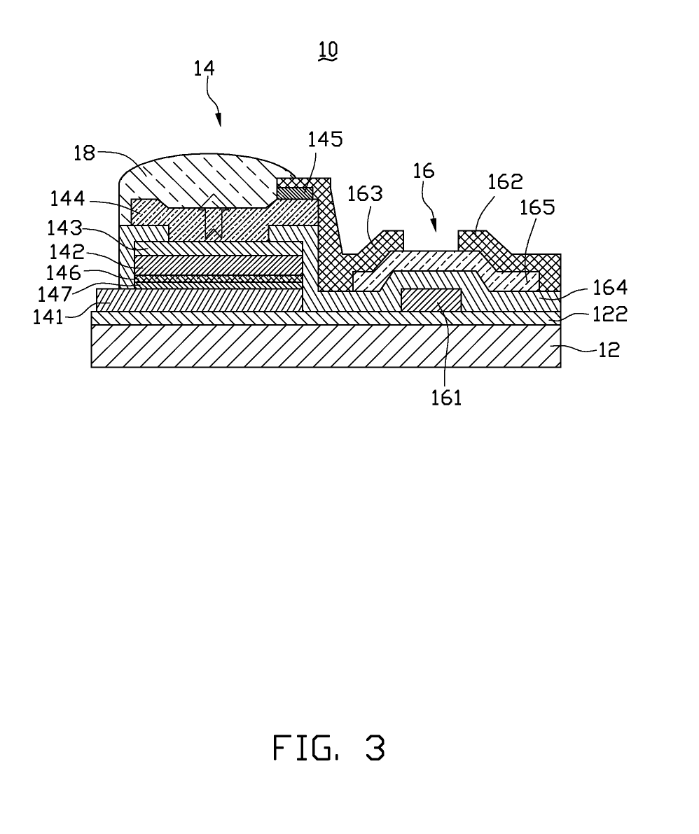

In addition, the solid state lighting element 14 in accordance with the first embodiment can further include a phosphor layer 18 as shown in FIG. 3. The phosphor layer 18 is arranged on the solid state lighting element 14. Referring to FIG. 3, the phosphor layer 18 is arranged on the n-type semiconductor layer 144 to form an encapsulation layer, which covers the top of the solid state lighting element 14. The phosphor layer 18 is excited by primary light emitted from the solid state lighting element 14 to emit secondary light with a different color which mixes with the primary light to generate white light. Preferably, a color filter (not shown) is located on the phosphor layer 18 to filter the white light into light of different colors, such as red light, green light and blue light.

The solid state lighting element 14 may emit ultraviolet light, blue light, blue-green light, green light or red light, which matches with the color of the phosphor layer 18. Preferably, the solid state lighting element 14 emits blue light which matches with the phosphor layer 18 having green or red fluorescent powder therein; or the solid state lighting element 14 emits ultraviolet light which matches with the phosphor layer 18 having red, green or blue fluorescent powder therein.

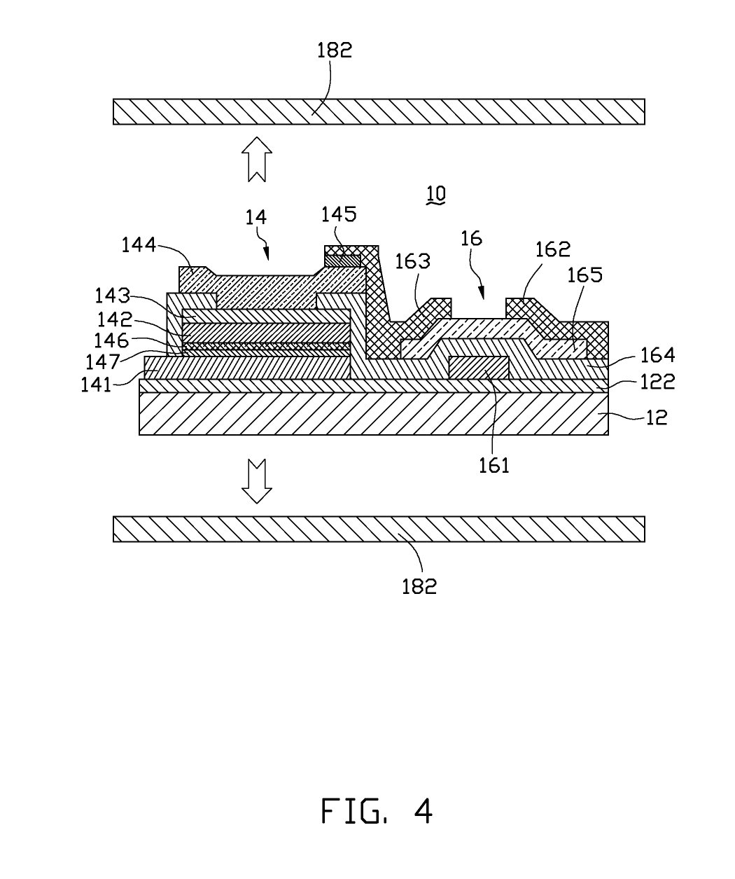

Referring to FIG. 4, the phosphor layer 18 may be a plate 182, and the plate 182 is located at an upper side of the solid state light display 10, or two plates 182 which are located at upper side and a lower side of the solid state light display 10 respectively. That is, the plate 182 is located on a light path of the solid state light display 10 and separated from the solid state light display 10 to form a remote phosphor structure.

According to the flip-chip solid state light display in this disclosure, because of the material properties of the solid state lighting element, and the solid state lighting element being mounted on the substrate by a way of flip-chip, the problem of degradation of organic materials in the manufacturing process of the solid state light display can be effectively solved, and the stability and reliability of the solid state light display is enhanced and the service life thereof is also extended.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A flip-chip solid state light display, comprising:
a substrate;
a plurality of solid state lighting elements; and
a plurality of thin film transistors;
wherein the solid state lighting elements and the thin film transistors are located on the substrate, the solid state lighting elements each are adjacent to one respective thin film transistor, the solid state lighting elements each are a light emitting diode, the solid state lighting elements each are mounted on the substrate by a way of flip-chip, the thin film transistors each electrically connect with a corresponding solid state lighting element by a source electrode or a drain electrode of each film transistor.

2. The flip-chip solid state light display of claim 1, wherein a buffer layer is arranged on the substrate, the buffer layer is electrically insulating, and the solid state lighting elements and the thin film transistors are arranged on the buffer layer.

3. The flip-chip solid state light display of claim 1, wherein the substrate is made of sapphire, silicon, silicon on insulator, glass, GaN, ZnO or plastic.

4. The flip-chip solid state light display of claim 1, wherein each solid state lighting element is an oxide semiconductor, a nitride semiconductor, a phosphide semiconductor, an arsenide semiconductor, or a compound semiconductor including III-V semiconductors, II-VI semiconductors, or IV-IV semiconductors.

5. The flip-chip solid state light display of claim 1, wherein each solid state lighting element is a p-n type light emitting diode, and includes a p-type electrode, a p-type semiconductor layer, a light emitting layer, an n-type semiconductor layer, and an n-type electrode, the light emitting layer is located on the p-type semiconductor layer, the n-type semiconductor layer is located on the light emitting layer, the n-type electrode is arranged on the n-type semiconductor layer, the p-type semiconductor layer is fixed to the substrate by the p-type electrode, and a bottom surface of the p-type semiconductor is near to the p-type electrode.

6. The flip-chip solid state light display of claim 5, wherein the n-type semiconductor layer is a metal oxide semiconductor and the metal oxide semiconductor is ZnO or IGZO as a transparent electrode of each solid state lighting element.

7. The flip-chip solid state light display of claim 5, wherein the n-type semiconductor layer is a compound semiconductor, the compound semiconductor is a III-V semiconductor.

8. The flip-chip solid state light display of claim 5, wherein a contact layer and a current spreading layer are located between the p-type semiconductor layer and the p-type electrode.

9. The flip-chip solid state light display of claim 5, wherein the light emitting layer is made of CdZnMgSeTe, AlGaIn, AlInGaAs, AlInGaN,ZnO, IGZO or SiGe.

10. The flip-chip solid state light display of claim 1, wherein each thin film transistor is located at a lateral side of a corresponding solid state lighting element, a gate electrode of each thin film transistor is located on the substrate, an insulation layer is arranged on the gate electrode, an active layer is located on the insulation layer, the source electrode and the drain electrode is arranged on the active layer.

11. The flip-chip solid state light display of claim 10, wherein each thin film transistor electrically connects with the corresponding solid state lighting element by a way of the source electrode or drain electrode of each thin film transistor electrically connecting with the n-type semiconductor layer, the p-type semiconductor layer, the n-type electrode or the p-type electrode of the corresponding solid state lighting element.

12. The flip-chip solid state light display of claim 10, wherein the active layer is made of a metal oxide semiconductor, low temperature poly-silicon, or amorphous silicon, the metal oxide semiconductor is an amorphous metal oxide semiconductor, a poly-silicon metal oxide semiconductor, a crystalline metal oxide semiconductor, a microcrystalline metal oxide semiconductor, or a nano metal oxide semiconductor.

13. The flip-chip solid state light display of claim 10, wherein the active layer comprises one element of In, Ca, Al, Zn, Cd, Ca, Mg, Sn or Pb.

14. The flip-chip solid state light display of claim 13, wherein the active layer is made of IGZO, which is a material also for forming a current spreading layer of each solid state lighting element.

15. The flip-chip solid state light display of claim 10, wherein the insulation layer is made of SiOₓ, SiON, SiNₓ, HfOₓ, AlOₓ, Ta₂O₅ or BaSrTiOₓ.

16. The flip-chip solid state light display of claim 10, wherein at lease one of the source electrode and the drain electrode is a transparent oxide electrode, or a metal electrode, or a transparent nonmetallic electrode.

17. The flip-chip solid state light display of claim 16, wherein the transparent oxide electrode is made of ITO, IZO, IGZO, AZO, or ATO.

18. The flip-chip solid state light display of claim 16, wherein the metal electrode contains one composition of Ni, Ti, Cr, Al, Au, Ag, Mo, Cu, Pt, Pd, Co, W, or an alloy thereof

19. The flip-chip solid state light display of claim 16, wherein the transparent nonmetallic electrode is made of graphene, carbon nanotubes, or graphite powder.

20. The flip-chip solid state light display of claim 1, wherein each solid state lighting element is a p-n type light emitting diode and includes a p-type electrode, a p-type semiconductor layer, a light emitting layer, an oxide semiconductor layer, and an n-type electrode, the n-type electrode contacts the substrate, and the n-type electrode electrically connects with the light emitting layer or the oxide semiconductor layer by extending through a through hole extending through the p-type semiconductor layer, the n-type electrode being electrically insulated from the p-type semiconductor layer.

21. The flip-chip solid state light display of claim 20, wherein a contact layer, a current spreading layer and a distributed bragg reflector layer are located between the p-type semiconductor layer and the n-type electrode.

22. The flip-chip solid state light display of claim 20, wherein each thin film transistor is located on the substrate, an active layer of each thin film transistor is located on the source electrode and the drain electrode of each thin film electrode, an insulation layer of each thin film transistor is arranged on the active layer, the gate electrode of each thin film electrode is located on the insulation layer, and the source electrode or the drain electrode electrically with the n-type electrode on the substrate.

23. The flip-chip solid state light display of claim 1 further comprising a phosphor, layer wherein the phosphor layer is arranged on each solid state lighting element.

24. The flip-chip solid state light display of claim 23, wherein the phosphor layer is a plate and located at a light path of the flip-chip solid sate light display and spaced from the flip-chip solid sate light display to form a remote phosphor structure.

25. The flip-chip solid state light display of claim 23, wherein a color filter is arranged on the phosphor layer for separating light from each solid state lighting element into light of different colors.

26. The flip-chip solid state light display of claim 25, wherein the different colors are red, blue or green.
